(19) United States
(12) Patent Application Publication
(10) Pub. No.: US 2026/0353872 A1
(43) Pub. Date: Nov. 5, 2026

(54) STACKED STRUCTURE AND FABRICATION METHOD OF THE STACKED STRUCTURE

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/723,183

(22) Filed: Jun. 29, 2026

Related U.S. Application Data
(63) Continuation of application No. PCT/JP2025/000024, filed on Jan. 6, 2025.

(30) Foreign Application Priority Data
Jan. 29, 2024 (JP) 2024-010778

(51) Int. Cl. H10H 20/825; H10H 20/00; H10H 20/01; H10H 20/815; H10H 20/82

(52) U.S. Cl. CPC H10H 20/825; H10H 20/01335; H10H 20/062; H10H 20/815; H10H 20/82

(57) ABSTRACT

The stacked structure includes a substrate and a semiconductor film located over the substrate and containing a Group 13 metal nitride. A bulk oxygen concentration in the semiconductor film decreases continuously or stepwise with increasing distance from the substrate. The manufacturing method of the stacked structure includes forming a semiconductor film containing a Group 13 metal nitride over a substrate, and the formation of the semiconductor film is performed so that a bulk oxygen concentration decreases continuously or stepwise with increasing distance from the substrate.

### CROSS-REFERENCE TO RELATED APPLICATIONS

This application is a Continuation of International Patent Application No. PCT/JP2025/000024, filed on Jan. 6, 2025, which claims the benefit of priority to Japanese Patent Application No. 2024-010778, filed on Jan. 29, 2024, the entire contents of which are incorporated herein by reference.

### FIELD

An embodiment of the present invention relates to a stacked structure containing a Group 13 metal nitride and a fabrication method thereof.

### BACKGROUND

In recent years, semiconductors containing nitrides of Group 13 metals of the periodic table, such as gallium nitride (GaN) and indium nitride (InN), have been applied to a variety of semiconductor devices including light-emitting diodes. Thin films of the Group 13 metal nitrides are generally fabricated over a single crystalline substrate such as a silicon substrate, a sapphire substrate, and a silicon carbide substrate with an organic-metal chemical vapor deposition (MOCVD) method. Recently, it has been found that thin films of Group 13 metal nitrides with relatively high crystallinity can be fabricated using a sputtering method (see, International Patent Application Publication No. 2022/259918, for example).

### SUMMARY

An embodiment of the present invention is a stacked structure. The stacked structure includes a substrate and a semiconductor film located over the substrate and containing a Group 13 metal nitride. A bulk oxygen concentration in the semiconductor film decreases continuously or stepwise with increasing distance from the substrate.

An embodiment of the present invention is a fabrication method of a stacked structure. The manufacturing method includes forming a semiconductor film containing a Group 13 metal nitride over a substrate. The formation of the semiconductor film is performed so that a bulk oxygen concentration decreases continuously or stepwise with increasing distance from the substrate.

An embodiment of the present invention is a semiconductor device including the aforementioned stacked structure.

### BRIED DESCRIPTION OF DRAWINGS

FIG. 1 is a schematic cross-sectional view of a stacked structure according to an embodiment of the present invention.

FIG. 2 is a schematic cross-sectional view of a stacked structure according to an embodiment of the present invention.

FIG. 3 is a schematic cross-sectional view of a stacked structure according to an embodiment of the present invention.

FIG. 4 is a schematic cross-sectional view showing a fabrication method of a stacked structure according to an embodiment of the present invention.

FIG. 5 is a schematic cross-sectional view of a light-emitting diode manufactured using a stacked structure according to an embodiment of the present invention.

FIG. 6 is a schematic cross-sectional view of a light-emitting diode manufactured using a stacked structure according to an embodiment of the present invention.

FIG. 7 is a schematic cross-sectional view of a transistor manufactured using a stacked structure according to an embodiment of the present invention.

FIG. 8 is a schematic cross-sectional view of a transistor manufactured using a stacked structure according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted. The reference number is used when plural structures which are the same as or similar to each other are collectively represented, while a hyphen and a natural number are further used when these structures are independently represented.

In the specification and the claims, an expression “a structure is exposed from another structure” means a mode in which a part of the structure is not covered by the other structure and includes a mode where the part uncovered by the other structure is further covered by another structure.

In the specification and the claims, an expression that “a structure is exposed from another structure” means a state where a portion of the structure is not covered by the other structure and also includes a state where the portion which is not covered by the other structure is covered with another structure. Here, the vertical relationship between the structure and the other structure is irrelevant. In addition, the state expressed by this expression includes a state where the structure is not in contact with the other structure.

### First Embodiment

In the present embodiment, a stacked structure according to an embodiment of the present invention and a fabrication method thereof are described.

### 1. Stacked Structure

### (1) Overall Structure

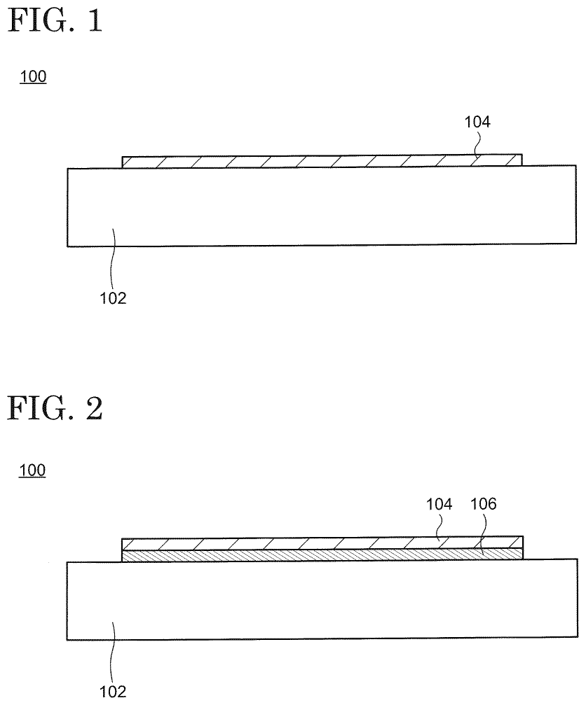

A schematic cross-sectional view of a stacked structure 100 according to an embodiment of the present invention is shown in FIG. 1. The stacked structure 100 has a substrate 102 and a semiconductor film 104 located over the substrate 102 and containing a Group 13 metal nitride. The substrate 102 and the semiconductor film 104 may be in direct contact with each other, or the stacked structure 100 may have a buffer layer 106 between the substrate 102 and semiconductor film 104 as an optional component (FIG. 2). A variety of patterned semiconductor films, insulating films, and conductive films may be formed over the stacked structure 100, by which a variety of semiconductor devices can be constructed. Thus, the stacked structure 100 also functions as a functional substrate for providing semiconductor devices.

### (2) Substrate

The substrate 102 may be a single crystalline substrate or an amorphous substrate. For example, a single crystalline or polycrystalline silicon substrate, a sapphire substrate, and a quartz substrate as well as a glass substrate and a plastic substrate may be used as the substrate 102. For example, a large rectangular amorphous glass substrate also known as mother glass may be used as the substrate 102. Specifically, a glass substrate having a size of 2160 mm×2460 mm and called the 8th generation mother glass, a glass substrate having a size of 2400 mm×2800 mm and called the 9th generation mother glass, a glass substrate having a size of 2880 mm×3130 mm and called the 10th generation mother glass, or an even larger glass substrate may be used. Materials contained in a plastic substrate include a polymer such as a polyimide, a polyamide, and a polycarbonate. The substrate 102 may be flexible.

### (3) Buffer Layer

The buffer layer 106 improves the adhesion between the substrate 102 and the semiconductor film 104 to prevent deformation (warpage) of the substrate 102 during the formation of the semiconductor film 104 or a variety of semiconductor films, insulating films, and conductive films provided over the semiconductor film 104 and also contributes to promoting crystallization of the semiconductor film 104. Therefore, it is possible to improve the crystallinity of not only the semiconductor film 104 but also a variety of films provided over the semiconductor film 104.

Specifically, the buffer layer 106 may contain an insulating material or a conductive material having a hexagonal-most-dense structure, a face-centered cubic structure, or a structure equivalent thereto. Here, the structure equivalent to the hexagonal-most-dense structure or the face-centered cubic structure includes a crystal structure in which the c-axis is not orthogonal to the a-axis and the b-axis. Therefore, the buffer layer 106 is oriented in the (0001) direction, that is, the c-axis direction with respect to the substrate 102 in this structure. In addition, the buffer layer 106 with the face-centered cubic structure or the structure equivalent thereto is oriented in the (111) direction with respect to the substrate 102. Hence, the c-axis of the buffer layer 106 is oriented in a direction perpendicular or almost perpendicular to a surface over which the buffer layer 106 is provided. The formation of a functional layer containing a compound semiconductor over the buffer layer 106 promotes crystal growth of the semiconductor film 104 in the c-axis direction, thereby improving crystallinity.

Such buffer layers 106 may contain a metal nitride such as aluminum indium nitride, aluminum nitride, aluminum potassium nitride, aluminum oxynitride, titanium nitride, and gallium nitride, a metal oxide such as zinc oxide, lithium niobate (LiNbO), BiLaTiO, SrFeO, BiFeO, BaFeO, ZnFeO, and PMnN-PZT, silicon, germanium, or basic calcium phosphate (biological apatite). The use of such materials allows the formation of an insulating buffer layer 106. In particular, the use of aluminum indium nitride can promote more effective c-axis orientation of the semiconductor film 104 because the lattice number shift between the buffer layer 106 and the semiconductor film 104 in contact with the buffer layer 106 can be reduced. Alternatively, the buffer layer 106 may contain a metal such as titanium, aluminum, silver, nickel, copper, strontium, rhodium, palladium, iridium, platinum, and gold. When a metal is included, the buffer layer 106 is conductive and functions as a wiring, allowing the buffer layer 106 to be used as a wiring.

### (4) Semiconductor Film

As described above, the semiconductor film 104 contains a Group 13 metal nitride. The semiconductor film 104 may consist of a Group 13 metal nitride. The Group 13 metal is selected from gallium, indium, and aluminum. Thus, the Group 13 metal nitrides include gallium nitride-based compound semiconductors such as gallium nitride, indium nitride, aluminum gallium nitride, and indium gallium nitride. The semiconductor film 104 may further contain a dopant such as silicon, germanium, magnesium, zinc, cadmium, and beryllium.

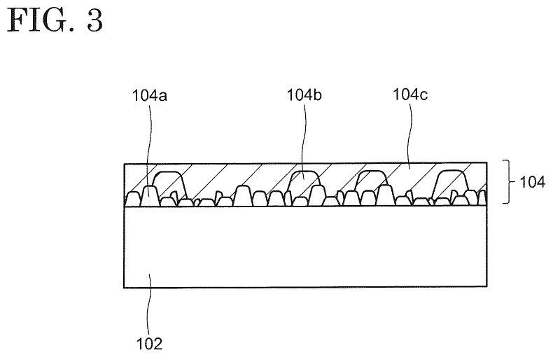

Here, the bulk oxygen concentration in the semiconductor film 104 decreases with increasing distance from the substrate 102. The bulk oxygen concentration may decrease continuously or stepwise. The crystallinity and planarity of the semiconductor film 104 are improved by controlling the bulk oxygen concentration in this manner. More specifically, the semiconductor film 104 may be composed of three layers. That is, as shown in FIG. 3, the semiconductor film 104 is composed of a first layer 104a in contact with the substrate 102 or the buffer layer 106, a second layer 104b located over the first layer 104a, and a third layer 104c located over the second layer 104b. The bulk concentration of oxygen decreases in the order of the first layer 104a, the second layer 104b, and the third layer 104c.

The first layer 104a contains or consists of a Group 13 metal nitride and has a thickness equal to or greater than 10 nm and equal to or less than 50 nm. The first layer 104a contains a crystal of a Group 13 metal nitride and is oriented in the c-axis direction with respect to the surface of the substrate 102. Moreover, the first layer 104a grows from the surface of the substrate 102 or the buffer layer 106 and exhibits a columnar shape. The first layer 104a functions as a so-called seed crystal to promote crystal growth of the second layer 104b. The first layer 104a may be distributed in an island shape over the substrate 102.

The second layer 104b also contains or consists of a Group 13 metal nitride. The second layer 104b is formed mainly by crystal growth of a Group 13 metal nitride from a portion of the surface of the first layer 104a and partially covers the first layer 104a. More specifically, the second layer 104b is formed by utilizing the first layer 104a as a seed crystal and allowing a Group 13 metal nitride to three-dimensionally grow from its surface (i.e., a normal direction of the substrate 102 and a direction perpendicular thereto). The thickness of the second layer 104b is greater than the thickness of the first layer 104 a and is equal to or greater than 300 nm and equal to or less than 500 nm, for example. The bulk concentration of oxygen in the second layer 104b is lower than that in the first layer 104a. For example, the bulk concentration of oxygen in the first layer 104a is equal to or greater than 1×10¹⁹ atoms/cm³ and equal to or less than 1×10²⁰ atoms/cm³, whereas the bulk concentration of oxygen in the second layer 104b is equal to or greater than 1×10¹⁸ atoms/cm³ and equal to or less than 1×10¹⁹ atoms/cm³. As described above, a Group 13 metal nitride undergoes crystal growth using the first layer 104a as a seed crystal. In addition, because the bulk concentration of oxygen is low, there are few crystal defects. Therefore, the second layer 104b exhibits high crystallinity.

The third layer 104c also contains or consists of a Group 13 metal nitride. The third layer 104c is formed by two-dimensional crystal growth of a compound semiconductor from the surface of the second layer 104b. That is, although the third layer 104c is formed by crystal growth of the compound semiconductor in the normal direction of the substrate 102 and the direction perpendicular thereto, the crystal growth rate of the latter is greater than that of the former. Therefore, the third layer 104c absorbs the projections and depressions caused by the first layer 104a and the second layer 104b and is formed as a layer with high surface planarity. The thickness of the semiconductor film 104, i.e., a distance from the interface between the substrate 102 and the semiconductor film 104 (an interface between the substrate 102 and the buffer layer 106 in the case where the buffer layer 106 is provided) to a top surface of the third layer 104c is, for example, equal to or greater than 1 μm and equal to or less than 3 μm. The bulk concentration of oxygen in the third layer 104c is lower than that of the second layer 104b and is equal to or greater than 1×10¹⁷ atoms/cm³ and equal to or less than 1×10¹⁸ atoms/cm³, for example. Moreover, the oxygen concentration at the surface of the third layer 104c is preferred to be equal to or less than 1×10¹⁷ atoms/cm³. Therefore, there are extremely few crystal defects caused by oxygen in the third layer 104c. In particular, the oxygen defects close to the surface are small, resulting in high crystallinity and surface flatness. For example, the arithmetic mean surface roughness of the surface of the third layer 104c is equal to or greater than 0.5 nm and equal to or less than 2 nm. The aforementioned bulk concentration of oxygen and the oxygen concentration at the surface can be estimated by secondary ion mass spectrometry (SIMS). The arithmetic mean surface roughness can be obtained by using an atomic force microscope (AFM).

Due to the high planarity of the third layer 104c, the planarity of a variety of films provided thereover is also improved. This feature contributes to improving the characteristics of semiconductor devices fabricated using the stacked structure 100. For example, in the case of fabricating a light-emitting diode by utilizing the stacked structure 100, a quantum well structure having alternatingly stacked layers of ultrathin films with a thickness of a few nanometers may be prepared to form an emission layer. At this time, the use of the stacked structure 100 allows the formation of the ultrathin films over a flat surface with few surface irregularities. Hence, it is possible to produce a light-emitting diode having a quantum well structure with a highly controlled structure, and as a result, a light-emitting diode with precisely controlled characteristics can be provided.

### 2. Fabrication Method of Stacked Structure

The fabrication method of the stacked structure 100 will be described below. As described above, the stacked structure 100 has a three-layer structure composed of the first layer 104a, the second layer 104b, and the third layer 104c. Moreover, the semiconductor film 104 has a decreasing bulk concentration of oxygen in the order of the first layer 104a, the second layer 104b, and the third layer 104c, that is, as the distance from the substrate 102 increases. In other words, the semiconductor film 104 is formed such that the bulk concentration of oxygen decreases with increasing distance from the substrate 102. As described below, the bulk oxygen concentration can be controlled as described above, and the semiconductor film 104 with high surface planarity and crystallinity can be formed by forming the semiconductor film 104 in three stages.

### (1) Formation of First Layer

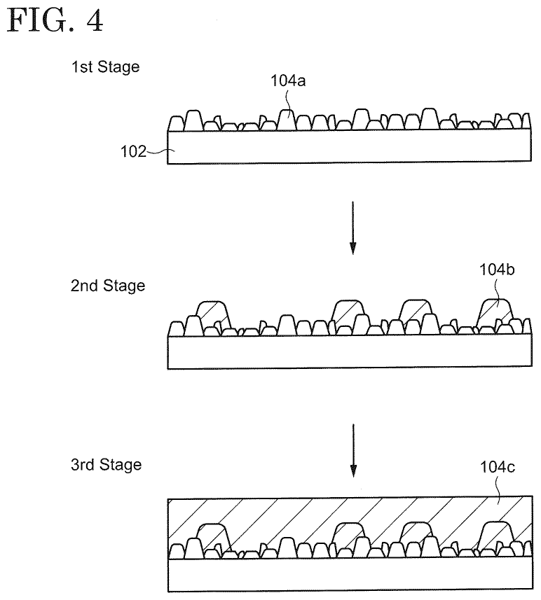

In the first stage which is the initial stage, the first layer 104a is formed (FIG. 4). The first layer 104a is formed over the substrate 102 or the buffer layer 106 by utilizing a sputtering method. Specifically, a sputtering target containing a Group 13 metal (zero-valent Group 13 metal), a sputtering target containing a Group 13 metal nitride, or a sputtering target containing a Group 13 metal nitride and a dopant is used, and nitrogen gas is used as a sputtering gas to perform sputtering at a pressure equal to or greater than 1×10⁻¹ Pa and equal to or less than 1 Pa, leading to the formation of the first layer 104a. The first layer 104a may be formed over the substrate 102 in an island shape, that is, the first layer 104a may be formed so that the substrate 102 is exposed between adjacent seed crystals. The temperature at this time may be selected from a range equal to or higher than 500 °C and equal to or lower than 600 °C, for example. Thus, even if a glass substrate with a relatively low melting point or strain point is used as the substrate 102, the first layer 104a can be formed over the substrate 102 without causing any deformation thereof.

### (2) Formation of Second Layer

The second layer 104b is formed in the second stage following the first stage (FIG. 4). As described above, the second layer 104b is formed through three-dimensional growth using the first layer 104a as a seed crystal. The second layer 104b can be formed by a sputtering method, a MOCVD method, or a molecular beam epitaxy (MBE) method. However, since the MOCVD method involves deposition at high temperatures, it is preferable to use the sputtering method or the MBE method when a glass substrate or a plastic substrate is used as the substrate 102.

When the second layer 104b is formed by a sputtering method, the second layer 104b may be formed in a similar manner to the formation of the first layer 104a. However, in order to form the second layer 104b having a lower bulk concentration of oxygen, the sputtering is performed so that the oxygen concentration in the sputtering gas is lower than that during the formation of the first layer 104a. That is, the sputtering is performed under the conditions where the partial pressure of oxygen in the atmosphere during the formation of the second layer 104b is lower than that during the formation of the first layer 104a. For example, a sputtering gas with a lower oxygen concentration compared to the sputtering gas used during the formation of the first layer 104a may be used during the formation of the second layer 104b. Alternatively, a reducing gas such as hydrogen gas may be mixed with the sputtering gas to reduce the oxygen concentration in the sputtering gas. This method causes a reaction between the reducing gas and oxygen during sputtering, resulting in a decrease in the concentration and the partial pressure of oxygen in the sputtering gas. When the reducing gas is included in the sputtering gas of the first stage sputtering, its concentration is lower than that of the second stage.

Alternatively, the oxygen concentration in the sputtering target may be controlled. That is, a sputtering target having a lower oxygen concentration than the sputtering target used during the formation of the first layer 104a may be used in the formation of the second layer 104b. This method reduces the amount of oxygen or oxygen-containing compounds repelled from the sputtering target, allowing the formation of the second layer 104b having a lower bulk oxygen concentration than the first layer 104a.

When applying the MBE method, a crucible filled with a Group 13 metal nitride which constitutes the semiconductor film 104 is heated under an ultrahigh vacuum equal to or greater than 1×10⁻⁸ Pa and equal to or less than 1×10⁻⁴ Pa, and the resulting molecular beam is applied onto the substrate 102 over which the first layer 104a is formed, for example. The deposition temperature at this time is, for example, equal to or higher than 700 °C and equal to or lower than 800 °C. Compared with the sputtering method for forming the first layer 104a, the pressure of the atmosphere in which the second layer 104b is formed by the MBE method is extremely low. Therefore, the partial pressure of oxygen in the atmosphere during the formation of the second layer 104b can be significantly reduced compared with that during the formation of the first layer 104a.

When a substrate with high heat resistance, for example, a silicon substrate, a sapphire substrate, or a silicon carbide substrate is used as the substrate 102, the second layer 104b may be formed using the MOCVD method. In the MOCVD method, an organometallic compound containing a Group 13 metal, such as trimethylgallium, trimethylindium, and trimethylaluminum may be used as a reactive gas, ammonia gas may be used as a nitrogen source, hydrogen gas and ammonium gas functioning as a carrier gas may be used, and the substrate 102 over which the first layer 104a is formed may be treated at a temperature equal to or higher than 800 °C and equal to or lower than 1100 °C under a pressure equal to or higher than atmospheric pressure and equal to or lower than 1×10⁵ Pa. The epitaxial crystal growth of the Group 13 metal nitride occurs during the deposition of the active species formed by thermal decomposition of the reactive gas and the nitrogen source over the first layer 104a, thereby resulting in the second layer 104b. In the MOCVD method, the partial pressure of hydrogen gas is relatively high and is equal to or greater than 2×10⁴ Pa and equal to or less than 5×10⁴ Pa, for example. Therefore, oxygen mixed into the deposition atmosphere can be effectively trapped. As a result, in the second stage, it is possible to perform the film formation in a deposition atmosphere with a lower oxygen partial pressure than that in the first stage, and the second layer 104b with a lower bulk oxygen concentration than the first layer 104a can be formed.

### (3) Formation of Third Layer

The third layer 104c is formed in the third stage following the second stage (FIG. 4). As described above, the third layer 104c is formed by two-dimensional growth of a Group 13 metal nitride over the second layer 104b. Similar to the second layer 104b, the third layer 104c may also be formed by a sputtering method, a MOCVD method, or an MBE method. However, when a glass substrate or a plastic substrate is used as the substrate 102, the sputtering method or the MBE method are preferred.

Since the third layer 104c can be formed in a similar manner to the second layer 104b, a detailed explanation is omitted. The third layer 104c is formed under the conditions where the partial pressure of oxygen in the atmosphere during the formation of the third layer 104c is lower than that during the formation of the second layer 104b. Therefore, when a sputtering method is used, sputtering is performed so that the oxygen concentration in the sputtering gas is lower than that during the formation of the second layer 104b in order to reduce the bulk concentration of oxygen than that of the second layer 104b. For example, a sputtering gas with a lower oxygen concentration than the sputtering gas used during the formation of the second layer 104b may be used during the formation of the third layer 104c. Alternatively, the concentration of the reducing gas in the sputtering gas during the formation of the third layer 104c may be set higher than that during the formation of the second layer 104b. Alternatively, a sputtering target having a lower oxygen concentration than the sputtering target used in the formation of the second layer 104b may be used in the formation of the third layer 104c.

When the MBE method is applied, the third layer 104c may be formed at a lower pressure than the pressure during the formation of the second layer 104b, by which the partial pressure of oxygen in the atmosphere during the formation of the third layer 104c can be decreased compared with that during the formation of the second layer 104b.

When the MOCVD method is used to form the third layer 104c, it is possible to form the third layer 104c having a much lower bulk oxygen concentration by setting the hydrogen gas concentration in the reactive gas during the formation of the third layer 104c to be higher than that during the formation of the second layer 104b.

When the buffer layer 106 is provided, the buffer layer 106 may be formed by a sputtering method, a CVD method, or the like as appropriate.

As described above, the formation of semiconductor film 104 is performed in such a way that the oxygen partial pressure in the deposition atmosphere decreases as the film grows, so that the semiconductor film 104 in which the bulk oxygen concentration decreases with increasing distance from the substrate 102 increases can be formed over the substrate 102 or the buffer layer 106. Therefore, the semiconductor film 104 with high crystallinity and high planarity of the uppermost layer can be formed.

### Second Embodiment

The stacked structure 100 described in the First Embodiment can be applied to a variety of semiconductor devices. In this embodiment, a light-emitting diode and a transistor are explained as a semiconductor device fabricated using the stacked structure 100 described above. An explanation of the structures the same as or similar to those described in the First Embodiment may be omitted.

### 1. Light-Emitting Diode

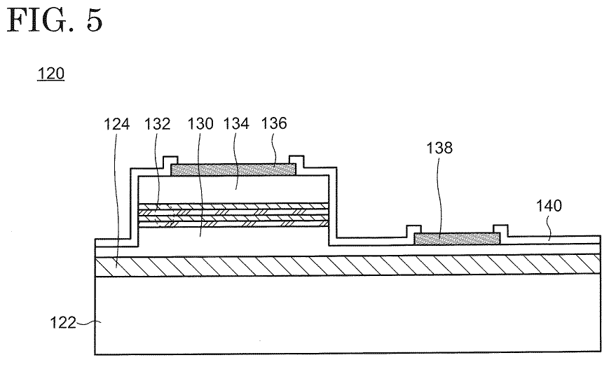

A schematic cross-sectional view of an example of a light-emitting diode 120 fabricated using the stacked structure 100 is shown in FIG. 5. The light-emitting diode 120 has a substrate 122 and further has an undoped gallium nitride layer (hereinafter, referred to as uGaN layer) 124 over the substrate 122. The light-emitting diode 120 further includes, over the uGaN layer 124, a laminate including an n-type cladding layer 130, a p-type cladding layer 134, and an emission layer 132 sandwiched between the n-type cladding layer 130 and the p-type cladding layer 134. In addition, the light-emitting diode 120 has an anode 136 and a cathode 138 respectively provided over the p-type cladding layer 134 and the n-type cladding layer 130. The light-emitting diode 120 may further have a protective film 140 and the like over the anode 136 and the cathode 138 as an optional component. The uGaN layer 124 with high crystallinity and planarity can be formed over the substrate 122 by applying the fabricating method of the semiconductor film 104 described in the First Embodiment.

The n-type cladding layer 130, the emission layer 132, and the p-type cladding layer 134 are configured to emit visible light when holes and electrons respectively injected from the anode 136 and cathode 138 are recombined. For example, the n-type cladding layer 130 may be configured to contain gallium nitride and a dopant imparting n-type conductivity such as silicon and germanium. On the other hand, the p-type cladding layer 134 may be configured to contain gallium nitride and a dopant imparting p-type conductivity such as magnesium, zinc, cadmium, and beryllium, for example. The n-type cladding layer 130 and the p-type cladding layer 134 may each have a single-layer structure or a multilayer structure composed of a plurality of layers with different compositions.

The emission layer 132 may have a single-layer structure of indium gallium nitride or may have a quantum well structure as shown in FIG. 5A, for example. A quantum well structure is a structure in which a plurality of thin films with different band gaps and having an extremely small thickness of 1 to 5 nm is alternately stacked, and alternating layers of indium gallium nitride and gallium nitride, alternating layers of indium gallium arsenide phosphide (GaInAsP) and indium phosphide (InP), and alternating layers of aluminum indium arsenide (AlInAs) and indium gallium arsenide (InGaAs), and the like are exemplified.

The anode 136 and the cathode 138 inject holes and electrons into the p-type cladding layer 134 and n-type cladding layer 130, respectively. As the anode 136, a thin film of a metal such as palladium, nickel, and gold, laminated films thereof, an alloy of these metals, or a conductive oxide transmitting visible light such as indium-tin mixed oxide (ITO) and indium-zinc mixed oxide (IZO) may be used, for example. As the cathode 138, a metal such as aluminum, titanium, gold, silver, chromium, and indium, laminated films of these metals, or an alloy of these metals may be used. Both the anode 136 and the cathode 138 may have a single-layer structure or a laminate of a plurality of films having different compositions.

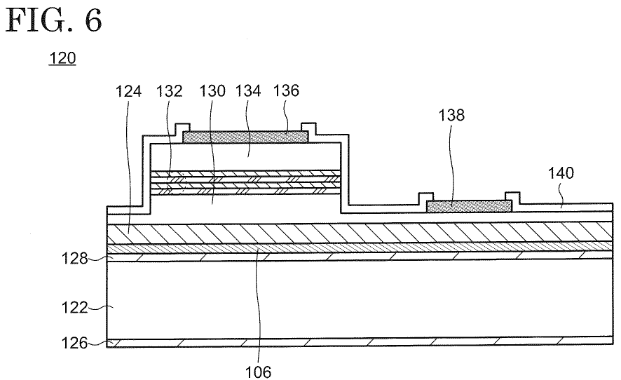

The substrate 122 corresponds to the substrate 102 of the First Embodiment and is selected from a high-melting point substrate such as a quartz substrate, a single crystal silicon substrate, a single crystal sapphire substrate, and a silicon carbide substrate. However, the substrate 122 may also be an amorphous glass substrate including alkali-free glass. In this case, the buffer layer 106 is provided over the substrate 122, and the uGaN layer 124 is formed thereover as shown in FIG. 6. It is preferable to provide an overcoat 128 and/or an undercoat 126 between the substrate 122 and the buffer layer 106 and under the substrate 122, respectively.

The buffer layer 106 improves the adhesion between the substrate 122 and the uGaN layer 124 to prevent deformation (warpage) of the substrate 122 under the high temperature conditions during the manufacture of the light-emitting diode 120. Furthermore, the buffer layer 106 contributes to promoting the crystallization of the uGaN layer 124 provided thereover in the c-axis direction. As described above, the fabrication method of the semiconductor film 104 described in the First Embodiment is applied to the uGaN layer 124. Therefore, even if an amorphous glass substrate is used as the substrate 122, the buffer layer 106 promotes the growth of the seed crystal in the c-axis direction, resulting in the formation of the first layer 104a with aligned crystal growth directions. Therefore, the crystallinity of the entire uGaN layer 124 including the first layer 104a as well as each layer provided thereover can also be improved. As a result, the light-emitting diode 120 having excellent characteristics can be provided.

The overcoat 128 is provided over the substrate 122 so as to be in contact with the substrate 122. The overcoat 128 prevents the diffusion of impurities such as alkali metal ions contained in the substrate 122. The overcoat 128 may be a single film or a laminate of a plurality of films containing a silicon-containing inorganic compound such as silicon oxide and silicon nitride. The undercoat 126 suppresses elimination of water and the like from the substrate 122 under the high temperature conditions during the manufacture of the light-emitting diode 120, prevents oxygen-containing impurities from entering the uGaN layer 124, the n-type cladding layer 130, the emission layer 132, the p-type cladding layer 134, and the like, and also prevents warpage of the substrate 122 caused by the difference in thermal expansion coefficient between the substrate 122 and the uGaN layer 124. A film containing aluminum nitride, a film containing aluminum oxide, or a laminate of these films may be used as the undercoat 126.

The protective film 140 is a component to prevent impurities such as oxygen and water from entering the light-emitting diode 120 and is composed of one or a plurality of films containing a silicon-containing inorganic compound such as silicon oxide and silicon nitride, for example. The protective film 140 is provided with openings to expose the anode 136 and the cathode 138, and wirings which are not illustrated are electrically connect to the anode 136 and cathode 138 using these openings.

Each of the layers structuring the light-emitting diode 120 described above can also be formed by a sputtering method. Therefore, deposition at a high temperature required by the epitaxial growth using the MOCVD method and the like is not required, and the light-emitting diode 120 can be fabricated without deformation of or damage to the substrate 122 even if the substrate 122 containing amorphous glass is used.

### 2. Transistor

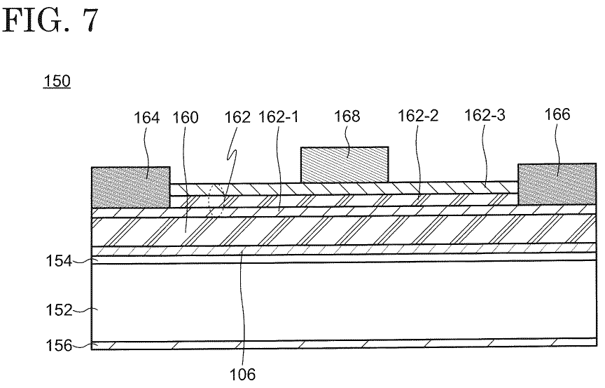

A schematic cross-sectional view of an example of a transistor 150 fabricated using the stacked structure 100 is shown in FIG. 7. The transistor 150 shown in FIG. 7 is a high electron-mobility field-effect transistor and includes a substrate 152 corresponding to the substrate 102 as well as the buffer layer 106 and an active layer (also called an electron-travelling layer) 160 over the substrate 152. The transistor 150 further includes an electron-supplying layer 162 over the active layer 160 as well as a gate electrode 168 and a pair of terminals (a first terminal 164 and a second terminal 166) located over the active layer 160 and electrically connected to the active layer 160 and the electron-supplying layer 162. The first terminal 164 and the second terminal 166 may be in contact with the active layer 160 or may be in contact with the active layer 160 through the electron-supplying layer 162 as shown in FIG. 7. The transistor 150 further includes an overcoat 154 and an undercoat 156. These configurations will be described below. However, since the substrate 152, the overcoat 154, the undercoat 156, and the buffer layer 106 are similar to the corresponding configurations of the light-emitting diode 120 described above, their explanation will be omitted. Furthermore, when a single crystal substrate with a high melting point is used as the substrate 122, the overcoat 154, the undercoat 156, and the buffer layer 106 may not be provided.

The stack of the active layer 160 and the electron-supplying layer 162 forms a path for the source/drain current when the transistor 150 is driven. The active layer 160 and the electron-supplying layer 162 include a Group 13 metal element and a Group 15 element. For example, the active layer 160 and the electron-supplying layer 162 may each include a gallium nitride-based or gallium arsenide-based compound semiconductor. In one example, the active layer 160 may be configured to contain undoped gallium nitride, while the electron-supplying layer 162 may be configured by a first electron-supplying layer 162-1 containing undoped aluminum gallium nitride, a second electron-supplying layer 162-2 containing undoped gallium nitride, and a third electron-supplying layer 162-3 containing p-type indium gallium nitride. The active layer 160 may be formed by applying the fabrication method of the semiconductor film 104 described in the First Embodiment.

The first terminal 164, the second terminal 166, and the gate electrode 168 each contain a metal such as aluminum, gold, silver, tantalum, molybdenum, titanium, and copper or an alloy containing one or a plurality of the above metals. Although not illustrated, a gate insulating film may be provided between the electron-supplying layer 162 and the gate electrode 168 as an optional component. The gate insulating film contains, for example, a silicon-containing inorganic compound such as silicon oxide and silicon nitride or a so-called high-k material such as hafnium silicate, zirconium silicate, hafnium oxide, and zirconium oxide. These components may also be formed by a vacuum evaporation method, an electron beam evaporation method, a CVD method, or a sputtering method.

In addition to the active layer 160, the electron-supplying layer 162 and the like may be formed using a patterning method. Therefore, deposition at a high temperature required by the epitaxial growth using the MOCVD method is not required, and these layers can be formed without deformation of or damage to the substrate 152, even if the substrate 152 containing amorphous glass is used. Even if an amorphous substrate is used as the substrate 152, growth of the seed crystals in the c-axis direction is promoted by the buffer layer 106, and the active layer 160 with aligned crystal growth direction can be formed. Therefore, the crystallinity of the entire active layer 160 including the first layer 104a as well as the electron-supplying layer 162 provided thereover can also be improved. These features enable the production of the transistor 150 with excellent characteristics.

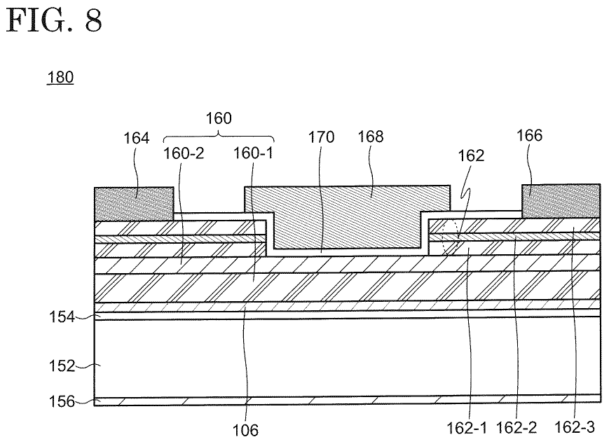

The transistors fabricated using the stacked structure 100 are not limited to the transistor 150 with the structure shown in FIG. 7. For example, the active layer 160 may have a bilayer structure as in the transistor 180 shown in FIG. 8. In this case, the active layer 160 may be composed of, for example, a first active layer 160-1 including undoped gallium nitride and a second active layer 160-2 including undoped aluminum gallium nitride. In the formation of the first active layer 160-1, the fabricating method of the semiconductor film 104 described in the First Embodiment is applied. There is also no restriction on the structure of the electron-supplying layer 162, and the electron-supplying layer 162 may be formed as a laminate of a first electron-supplying layer 162-1 including undoped gallium nitride, a second electron-supplying layer 162-2 including n-type gallium nitride, and a third electron-supplying layer 162-3 including undoped gallium nitride, for example. The gate insulating film 170 is provided between active layer 160 and the gate electrode 168. The gate insulating film 170 may be configured to include aluminum oxide, the silicon-containing inorganic compound, or the high-k material described above.

In the transistor 180, not only the buffer layer 106, the gate insulating film 170, the gate electrode 168, the first terminal 164, and the second terminal 166, but also the extremely thin active layer 160, which determines the characteristics of the transistor 180, can be formed by a sputtering method. As described above, since the first active layer 160-1 disposed over the substrate 152 is formed by applying the deposition method according to an embodiment of the present invention, the planarity of the top surface thereof is high. Therefore, the planarity of each layer formed over the first active layer 160-1 is also improved, and as a result, the structure of each layer can be precisely controlled. This feature contributes to the mass production of the transistor 180 with highly controlled characteristics.

The aforementioned modes described as the embodiments of the present invention can be implemented by appropriately combining with each other as long as no contradiction is caused. Furthermore, any mode which is realized by persons ordinarily skilled in the art through the appropriate combination, addition, deletion, or design change of elements or through the addition, deletion, or condition change of a process according to each embodiment is included in the scope of the present invention as long as they possess the concept of the present invention.

It is understood that another effect different from that provided by each of the aforementioned embodiments is achieved by the present invention if the effect is obvious from the description in the specification.

What is claimed is:

1. A stacked structure comprising:
a substrate; and
a semiconductor film located over the substrate and containing a Group 13 metal nitride,
wherein a bulk oxygen concentration in the semiconductor film decreases continuously or stepwise with increasing distance from the substrate.

2. The stacked structure according to claim 1,
wherein the semiconductor film comprises:
a first layer containing a columnar crystal containing the Group 13 metal nitride and having a thickness equal to or greater than 10 nm and equal to or less than 50 nm;
a second layer located over the first layer, containing the Group 13 metal nitride, and having a thickness equal to or greater than 300 mm and equal to or less than 500 nm; and
a third layer located over the second layer and containing the Group 13 metal nitride, and
a thickness of the semiconductor film is equal to or greater than 1 μm and equal to or less than 3 μm.

3. The stacked structure according to claim 2,
wherein the bulk oxygen concentration decreases in an order of the first layer, the second layer, and the third layer.

4. The stacked structure according to claim 2,
wherein the columnar crystal is c-axis oriented with respect to a surface of the substrate.

5. The stacked structure according to claim 2,
wherein an arithmetic mean surface roughness of a surface of the third layer is equal to or greater than 0.5 nm and equal to or less than 2 nm.

6. The stacked structure according to claim 2,
wherein the bulk oxygen concentration of the first layer is equal to or greater than 1×10¹⁹ atoms/cm³ and equal to or less than 1×10²⁰ atoms/cm³,
the bulk oxygen concentration of the second layer is equal to or greater than 1×10¹⁸ atoms/cm³ and equal to or less than 1×10¹⁹ atoms/cm³, and
the bulk oxygen concentration of the third layer is equal to or greater than 1×10¹⁷ atoms/cm³ and equal to or less than 1×10¹⁸ atoms/cm³.

7. The stacked structure according to claim 6,
wherein an oxygen concentration at a surface of the third layer is equal to or less than 1×10¹⁷ atoms/cm³.

8. The stacked structure according to claim 7,
wherein the bulk oxygen concentration and the oxygen concentration at the surface of the third layer are estimated by secondary ion mass spectrometry.

9. The stacked structure according to claim 1,
wherein the substrate is selected from a glass substrate, a quartz substrate, a single crystalline silicon substrate, a sapphire substrate, and a silicon carbide substrate.

10. The stacked structure according to claim 1,
wherein the Group 13 metal nitride is selected from gallium nitride and indium nitride.

11. A fabrication method of a stacked structure comprising forming a semiconductor film containing a Group 13 metal nitride over a substrate,
wherein the formation of the semiconductor film is performed so that a bulk oxygen concentration decreases continuously or stepwise with increasing distance from the substrate.

12. The fabrication method according to claim 11,
wherein the formation of the semiconductor film is performed so that an oxygen partial pressure in a deposition atmosphere decreases as the semiconductor film grows.

13. The fabrication method according to claim 11,
wherein the formation of the semiconductor film comprises:
forming, over the substrate, a first layer containing the Group 13 metal nitride and having a thickness equal to or greater than 10 nm and equal to or less than 50 nm with a sputtering method;
forming, over the first layer, a second layer containing the Group 13 metal nitride and having a thickness equal to or greater than 30 nm and equal to or less than 500 nm; and
forming a third layer containing the Group 13 metal nitride over the second layer,
wherein a thickness of the semiconductor film is equal to or greater than 1 μand equal to or less than 3 μm.

14. The fabrication method according to claim 13,
wherein the second layer and the third layer are formed with a sputtering method, and
an oxygen partial pressure in a deposition atmosphere during the formation of the second layer is lower than that during the formation of the first layer and higher than that during the formation of the third layer.

15. The fabrication method according to claim 13,
wherein the second layer and the third layer are formed with a sputtering method, and
a hydrogen partial pressure in a deposition atmosphere during the formation of the second layer is higher than that during the formation of the first layer and lower than that during the formation of the third layer.

16. The fabrication method according to claim 13,
wherein the second layer and the third layer are formed with a sputtering method, and
oxygen concentrations in sputter targets used in the formation of the first layer, the second layer, and the third layer decrease in this order.

17. The fabrication method according to claim 13,
wherein the second layer and the third layer are formed with a metal-organic vapor deposition method or a molecular beam epitaxy method, and
an oxygen partial pressure of a deposition atmosphere during the formation of the second layer is lower than that during the formation of the first layer and higher than that during the formation of the third layer.

18. The fabrication method according to claim 11,
wherein the Group 13 metal nitride is selected from gallium nitride and indium nitride.

19. The fabrication method according to claim 11, further comprising forming a buffer layer before forming the semiconductor film,
wherein the buffer layer contains at least one of aluminum nitride, indium aluminum nitride, aluminum gallium nitride, aluminum oxide, aluminum oxynitride, titanium nitride, titanium, aluminum, silver, nickel, and copper.

20. The fabrication method according to claim 11,
wherein the substrate is selected from a glass substrate, a quartz substrate, a single crystalline silicon substrate, a sapphire substrate, and a silicon carbide substrate.
